(19) United States
(12) Patent Application Publication
(10) Pub. No.: US 2020/0233476 A1
(43) Pub. Date: Jul. 23, 2020

(54) Computer system and system board

(71) Applicant: FUJITSU LIMITED, Kawasaki-shi (JP)

(72) Inventors: Sergej Beljaev, München (DE); Simon Czermak, München (DE)

(73) Assignee: FUJITSU LIMITED, Kawasaki-shi (JP)

(21) Appl. No.: 16/677,233

(22) Filed: Nov. 7, 2019

(30) Foreign Application Priority Data
Jan. 17, 2019 (DE) 102019101198.1

(51) Int. Cl. G06F 1/30; G01R 31/40; G01R 31/02

(52) U.S. Cl. CPC G06F 1/30; G01R 31/025; G01R 31/40

(57) ABSTRACT

The invention relates to a computer system including at least one power supply for providing a standby voltage and at least one system board with a plurality of system components arranged thereupon. A first group of system components of the plurality of system components is connected to the at least one power supply via a first supply path for providing the standby voltage. A second group of system components, different from the first group, of the plurality of system components is connected to the at least one power supply via a second supply path for providing the standby voltage which is electrically independent of the first supply path. The described computer system or the described system board allow reliable provision of a standby voltage for system-critical components of the computer system.

### BACKGROUND OF THE INVENTION

The invention relates to a computer system comprising at least one power supply for providing a standby voltage and at least one system board with a plurality of system components arranged thereupon. The invention further relates to a system board for such a computer system.

In known computer systems any components of a system board and any expansion cards plugged thereon, if required, are powered by a common 3.3 V supply path. For example, for especially powerful and/or components which have been later plugged in a respective socket or plug connector of the system board, short-circuits or failures in the voltage supply may occur which may impair other components arranged on the system board, which affects the operational reliability of the computer system as a whole.

In this context it is an object of the invention to describe an improved computer system and an improved system board, respectively, which enhance the operational reliability of the computer system and the system board.

### SUMMARY OF THE INVENTION

According to a first aspect of the invention said object is solved by a computer system of the kind described above, wherein a first group of system components of the plurality of system components is connected to the at least one power supply via a first supply path for providing the standby voltage, and wherein a second group of system components, different from the first group, of the plurality of system components is connected to the at least one power supply via a second supply path which is electrically independent of the first supply path for providing the standby voltage.

By means of an electrical separation of a first supply path and a second supply path, predetermined groups of system components may be electrically separated from one another, thus e.g. the occurrence of a failure in a system component of the first group does not result in an impairment of a system component of the second group.

For example, in the first group especially failure-prone system components, and in the second group system components which are less prone to failure may be grouped. Alternatively or in addition, a separation may also be performed according to that that those components are combined in the first group which are of minor importance for operating the computer system, while in the second group those system components are combined, which are essential for operating the computer system.

For example, the first group of system components comprises at least one of the following components: a voltage regulator for powering or supplying a central data processing unit, in particular a processor, and/or a plug connector for receiving an expansion card. The second group of system components includes at least one part of a chipset, a system monitoring module, a sequencing controller, and/or a power supply controller, for example.

The components mentioned first typically have a high electrical power consumption above the average and are often connected to the system board via respective sockets or plug connectors in a pluggable way. The two features quite often result in causing electrical troubles in the computer system. However, the components of the second group are typically firmly soldered to the system board and have only a small energy consumption. Due to that they normally do not impair the electrical safety of the system board. In addition, these components are e.g. important to detect failures in the computer system, which may occur, and are able to signal failures to an external monitoring component, if required.

In at least one configuration, the power supply comprises at least one first voltage transformer for generating the standby voltage for the system components connected to the first supply path, and at least one second voltage transformer, independent of the first voltage transformer, for generating the standby voltage for the system components connected to the second supply path. With such a complete separation of the voltage supply, a supply of the second group of system components may even be ensured when an electric failure occurs in the power supply itself, e.g. in the first voltage transformer.

The system components of the second group may detect an occurring failure in the area of the first supply path and signal it to a higher level monitoring component, which is independent of the computer system. Alternatively or in addition, a power supply controller of the computer system may deactivate the provision of the standby voltage via at least the first supply path when receiving an error signal to prevent possible subsequent damages, as for example an overloading of the power supply or a burn-through of further components of the system board.

The object mentioned above is also solved by a system board for usage in a computer system having at least one first electric conductor track for supplying a standby voltage to a first group of system components, and at least one second electric conductor track, separated from of the first electric conductor track, for supplying a standby voltage to a second group of system components, which is different from the first group. The first group of system components includes at least one component, which is releasably, e.g. pluggably connected to the system board, and the second group of system components exclusively includes such components, which are firmly connected, e.g. soldered, to the system board. Regarding the advantages and further configurations of such a system board, reference is made to the above.

Further advantageous configurations of the inventions are described in the appended dependent claims and in the following description by means of exemplary embodiments. The exemplary embodiments will be described with reference to the appended figures.

### BRIEF DESCRIPTION OF THE DRAWINGS

FIG. 1 shows a traditional diagram for providing a standby voltage in a computer system,

FIG. 2 shows a diagram for providing a standby voltage in a computer system according to the invention, and

FIG. 3 shows a computer system including a system board according to a configuration of the invention.

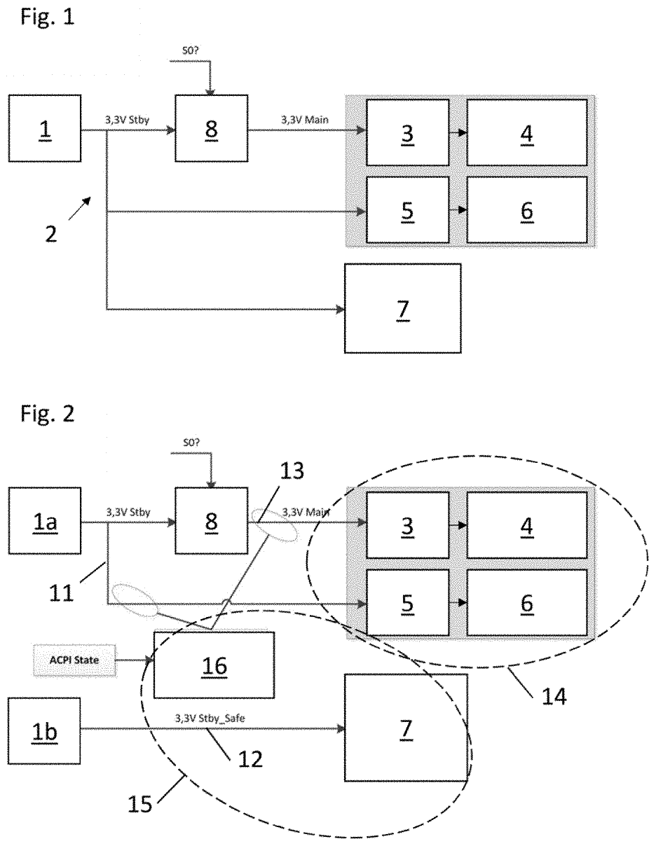

Before the invention is explained in detail in the following, first a conventional diagram for providing a standby voltage in a computer system is described with reference to FIG. 1. Typically computer systems comprise a single voltage regulator 1 for providing a regulated standby voltage of 3.3V (3.3V Stdby.)

The standby voltage is distributed via an electrical distribution structure 2 including a plurality of branches to a variety of system components. In the diagram according to FIG. 1, the system components comprise e.g. a voltage regulator 3 of a processor 4, and a plug connector 5 for receiving an expansion card 6. Finally, the supply voltage is also forwarded to a chipset 7.

In an embodiment according to FIG. 1, the voltage regulator 3 of the processor 4 is connected to the voltage transformer 1 via an interruption device 8. The interruption device 8 switches the 3.3V standby voltage to the voltage regulator 3 only in case the computer system is in an operational state, for example the ACPI state S0 (3.3V Main). In addition, a voltage supply is also possible in a sleep state (ACPI S1 or S2), if appropriate. In other operational states, e.g. in a switched off state (ACPI S5), an idle state (ACPI S4) and/or a standby state (ACPI S3), the interruption device 8 interrupts the 3.3V standby voltage for the voltage regulator 3.

The components 3, 4, and 6 are typically plugged in the respective socketw or plug connectors 5 of a system board. In addition, they have a relatively high electrical power, as for example 75 W per plug connector 5. Due to a faulty plug operation or unfavorable thermal conditions, such components may thus quite easily cause a short-circuit or any other overload of the voltage transformer 1. As in the supply diagram according to FIG. 1, the chipset 7 is connected to the other components 3 to 6 in parallel, it also fails when such an failure occurs, thus any functionality of the computer system may not be ensured anymore.

FIG. 1 shows an enhanced supply schema for providing a 3.3V standby voltage according to a configuration of the invention. Here, the supply schema according to FIG. 2 comprises a first voltage transformer 1a for providing a first standby voltage of 3.3V (3.3V Stby), and a second voltage transformer 1b for providing a second standby voltage of 3.3V (3.3V Stdby Safe). Instead of two completely electrically separate voltage transformers 1d and 1b, also a single voltage transformer including two electrically separated supply outputs may be provided. For example, the outputs may be electrically separated from each other by fuses or current limiting circuits.

The first standby voltage of the first voltage transformer 1a is provided via a first electrical supply path 11, one or more plug connectors 5, and expansion cards 6 received therein. The second standby voltage of the second voltage transformer 1b is supplied via a second supply path 12, which is electrically completely separated therefrom, exclusively to one or more system critical components, in the exemplary embodiment to chipset 7. In addition, as described above, the first standby voltage may also be coupled to a third supply path 13 via an interruption device 8 depending on an operation mode of the computer system. For example, the third supply path 13 serves to provide a voltage regulator 3 for a downstream processor 4 with operating power.

In the supply diagram according to FIG. 2, the components 3 to 6 form a first group 14 of system components, wherein electrical failures occur relatively often. In contrast, a second group 15 includes the chipset 7 and other critical and less failure-prone components of a system board. In case an electrical failure occurs within the first group 14, thus the components of the second group 15 may continuously provided with operating power.

In an advantageous configuration, the second group 15 further comprises an internal monitoring device 16 which is capable of monitoring the state of the first standby voltage and to forward an respective failure to other internal or external components of the computer system, even if an electrical short-circuit of one of the components of the first group 14 or along the first supply path 11 or a third supply path 13 has occurred. In addition, the monitoring device 16 may detect and forward further states, as e.g. an ACPI state of the computer system, which allows to deduce information about an operating state of the computer system.

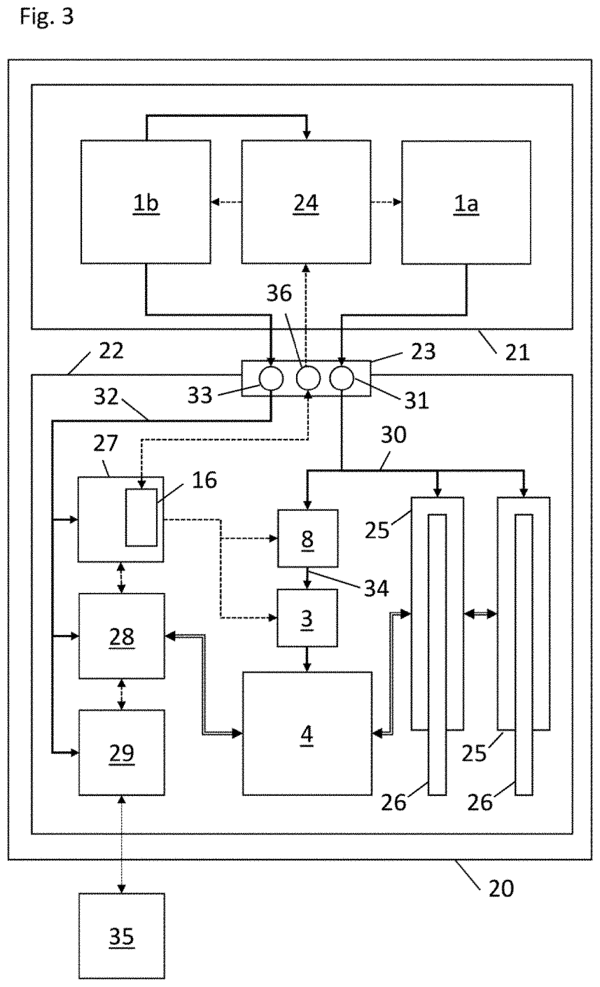

FIG. 3 shows an exemplary embodiment of the computer system 20 having a power supply 21 and a system board 22. The power supply 21 and the system board 22 are connected via a multi-pole plug connector 23 to each other. By means of this plug connector different supply voltages, which are indicated in FIG. 3 in bold, including a standby voltage of 3.3V, are provided to the system board 22 by the power supply 21. Furthermore, by means of the plug connector 23 control signals may also be exchanged with the system board 22 via wires, which are shown as dashed lines in FIG. 3, e.g. for controlling and monitoring the power supply 21 itself.

The power supply 21 includes a first voltage transformer 1a, a second voltage transformer 1b, and a power supply controller 24. In the exemplary embodiment, the first voltage transformer 1a has a higher electrical output power than the second voltage transformer 1b.

In the exemplary embodiment, the system board 22 includes two PCIe plug connectors 25 for receiving corresponding PCIe expansion cards 26, a voltage regulator 3 for providing an adequate core voltage for a processor 4 connected thereto, a sequencing controller 27, a so-called PCH module 28 (platform controller hub) which constitutes an essential component of the chipset, and a system management module 29 for remote maintenance and monitoring of the computer system 20. The PCIe plug connectors 25 are directly connected to a first plug contact 31 of the plug connector 23 via a first conductor track 30. By means of this plug contact 31, the standby voltage (3.3V Stdby) of the first voltage transformer 1a is provided to the first voltage transformer 1a of the power supply 21. The sequencing controller 27, the PCH module 28, and the system management module 29 are directly connected to a corresponding second plug contact 33 via a second conductor track 32 by means of which the standby voltage (3.3V stby_Safe) of the second voltage transformer 1b of the power supply 21 is provided. The voltage regulator 3 of the processor 4 is connected to a disruption device 8 via a third conductor track 34. By means of the disruption device 8 an indirect electrical connection to the first conductor track 30 and thus to the 3.3V standby voltage of the first voltage transformer 1a may be established.

As described above referring to FIG. 2, in the computer system 20 according to FIG. 3 two supply paths, which are electrically separated from each other, are thus provided for providing a standby voltage of 3.3V. In case an electrical failure occurs in the area of a first group of system components, including the voltage regulator 3, the processor 4, the PCIe plug connector 25, and the PCIe expansion card 26, the components of a second group, including the sequencing controller 27, the PCH module 28, and the system management module 29, may continuously be provided with the standby voltage of 3.3V. This secure standby voltage is provided in an independent way, and also serves to power the power supply controller 24 within the power supply, amongst others.

In normal operating mode, the sequencing controller 27 activates and deactivates the various system components of the printed circuit board 22, respectively, in response to predetermined control signals and predetermined time schedules. In addition, an internal monitoring device 16 of the sequencing controller 27 monitors the provision of various voltages by the power supply 21, and the voltage level of the conductor tracks 30 and 34, respectively. In case a deviation of an expected desired range occurs, the monitoring device 16 signals this to the sequencing controller 27, the PCH module 28, the system management module 29 and/or the power supply controller 24.

As shown in FIG. 3, the system management module 29 may then forward a respective error signal to a higher level monitoring component 35 in order to inform a system administrator of the computer system 20 about the failure, for example. Alternatively or in addition, the sequencing controller 27 may notify the power supply controller 24 via a third plug contact 36 that a failure has occurred. The power supply controller 24 may then completely deactivate the first voltage transformer 1a to prevent an overload of the power supply 21. Optionally, the power supply controller 24 may also deactivate the second voltage transformer 1b, after an alert has been successfully transmitted to the higher-level monitoring component 35.

By the disclosed concept of providing a standby voltage in a computer system, a group of system components may be supplied with the standby voltage independently of a second group of system components. This way, it is e.g. possible to separate a potentially dangerous first supply path from a not or less potentially dangerous supply path, which is especially vital for operation of the computer system. Thus in case of a failure, critical components are able to continue working and forward possible error messages to a monitoring component which is independent from the computer system. Further, they are able to shut down the computer system in a controlled way to prevent any further damage.

### LIST OF REFERENCE NUMERALS

1, 1a, 1b Voltage transformer
2 Electrical distribution structure
3 Voltage regulator
4 Processor
5 Plug connector
6 Expansion card
7 Chipset
8 Disruption device
11 First supply path
12 Second supply path
13 Third supply path
14 First group (of system components)
15 Second group (of system components)
16 (Internal) monitoring device
20 Computer system
21 Power supply
22 System board
23 Plug connector
24 Power supply controller
25 PCIe plug connector
26 PCIe expansion card
27 Sequencing controller
28 PCH module
29 System management module
30 First conductor track
31 First plug contact
32 Second conductor track
33 Second plug contact
34 Third conductor track
35 (Superior) monitoring component
36 Third plug contact

1. A computer system, comprising:
at least one power supply for providing a standby voltage; and
at least one system board with a plurality of system components arranged thereupon; wherein
a first group of system components of the plurality of system components is connected to the at least one power supply via a first supply path for providing the standby voltage; and
a second group of system components, different from the first group, of the plurality of system components is connected to the at least one power supply via a second supply path for providing the standby voltage which is electrically independent of the first supply path.

2. The computer system according claim 1, wherein the first group of system components includes at least one of the following components:
a voltage regulator for supplying a central data processing unit; and
a plug connector for receiving an expansion card.

3. The computer system according to claim 1, wherein the second group of system components includes at least one of the following components: at least one part of a chipset; a system monitoring module; a sequencing controller; and a power supply controller.

4. The computer system according to claim 1, wherein the first group of system components includes at least one component, which is releasably connected to the system board, and the second group of system components exclusively includes such components, which are fixedly connected to the system board.

5. The computer system according to claim 1, wherein the at least one power supply comprises at least one first voltage transformer for generating the standby voltage for system components connected to the first supply path, and at least one second voltage transformer, independent of the first voltage transformer, for generating the standby voltage for the system components connected to the second supply path.

6. The computer system according to claim 1, wherein the at least one power supply comprises at least one voltage transformer with two separate supply outputs, wherein the two supply outputs are electrically separated from one another via at least one of a fuse and current-limiting circuit.

7. The computer system according to claim 1, further comprising at least one internal monitoring device, which is configured to detect a drop in voltage and/or a short-circuit of a system component connected to the first supply path, and, upon detection of a drop in voltage or a short-circuit, to provide an error signal for at least one predetermined system component of the second group.

8. The computer system according to claim 7, wherein the at least one predetermined system component is configured to signal a failure of the computer system to a higher level monitoring component, independent of the computer system, if the error signal is provided by the internal monitoring device.

9. The computer system according to claim 7, wherein the internal monitoring device is configured to provide the error signal to a power supply controller of the computer system, and the power supply controller is configured to deactivate the provisioning of the standby voltage via at least the first supply path upon receipt of the error signal.

10. The computer system according to claim 1, further comprising an interrupter device which is configured to selectively interrupt or establish an electrical connection between the first supply path and a third supply path depending upon at least on control signal, wherein
the interrupter device interrupts the electrical connection if the control signal indicates that the computer system is in a switched-off state, an idle state and/or a stand-by state, and establishes the electrical connection, if the control signal indicates that the computer system is in a switched-on state and/or a sleep state.

11. The computer system according to claim 10, wherein the standby voltage corresponds to a standby voltage of 3.3 V, and at least one system component with a regular supply voltage of 3.3 V is connected to the third supply path.

12. A system board, comprising:
at least one first electrical conductor track for supplying a first group of system components with a standby voltage; and
at least one second electrical conductor track, electrically separated from the first electrical conductor track, for providing a second group of system components, different from the first group, with the standby voltage; wherein
the first group of system components includes at least one component which is releasably connected to the system board, and
the second group of system components exclusively includes components, which are fixedly connected to the system board.

13. The system board according to claim 12, wherein the first group of system components includes at least one of the following components:
a voltage regulator for supplying a central data processing unit; and
a plug connector for receiving an expansion card.

14. The system board according to claim 12, wherein the second group of system components includes at least one of the following components: at least one part of a chipset; at system monitoring module; a sequencing controller; and a power supply controller.

15. The system board according to claim 12, further comprising at least one plug connector for connecting the system board with a power supply, wherein the at least one plug connector includes a first plug contact, electrically connected to the first electrical conductor track, and a second plug contact electrically connected to the second conductor track.
